(19) United States
(12) Patent Application Publication
(10) Pub. No.: US 2026/0283018 A1
(43) Pub. Date: Sep. 17, 2026

(54) SEMICONDUCTOR PACKGE

(71) Applicant: Samsung Electronics Co., Ltd., Suwon-si (KR)

(72) Inventors: Hyunsoo Chung, Suwon-si (KR); Kwangsoo Kim, Suwon-s (KR); Seokbeom Yong, Suwon-si (KR)

(73) Assignee: Samsung Electronics Co., Ltd., Suwon-si (KR)

(21) Appl. No.: 19/313,286

(22) Filed: Aug. 28, 2025

(30) Foreign Application Priority Data
Mar. 11, 2025 (KR) 10-2025-0031655

(51) Int. Cl. H01L 25/18; H01L 23/00; H01L 23/373; H01L 23/498; H01L 23/538; H01L 23/60; H01L 25/065; H10B 80/00; H10D 80/30

(52) U.S. Cl. CPC H10W 90/00; H10B 80/00; H10D 80/30; H10W 40/258; H10W 42/60; H10W 70/611; H10W 90/401; H10W 90/701; H10W 72/823; H10W 72/884; H10W 90/24; H10W 90/724; H10W 90/732; H10W 90/754

(57) ABSTRACT

Provided is a semiconductor package including a first redistribution substrate, a chip stacked structure including a first sub-stack and a second sub-stack arranged on the first sub-stack, wherein the first sub-stack and the second sub-stack includes a plurality of semiconductor chips respectively, a second redistribution substrate arranged on the chip stacked structure, a first sub-stack vertical wiring unit including vertical wires configured to connect each of the semiconductor chips constituting the first sub-stack to the first redistribution substrate and extend to an upper surface of the first redistribution substrate in a vertical direction, and a second sub-stack vertical wiring unit including vertical wires configured to connect each of the semiconductor chips constituting the second sub-stack to the second redistribution substrate and extend to a lower surface of the second redistribution substrate in the vertical direction.

### CROSS-REFERENCE TO RELATED APPLICATIONS

This present application claims priority to and the benefit under 35 U.S.C. § 119(a)-(d) of Korean Patent Application No. 10-2025-0031655, filed on Mar. 11, 2025, in the Korean Intellectual Property office, the entire disclosure of which is incorporated herein by reference.

### BACKGROUND

Electronic devices have become more compact and lighter due to the rapid development of the electronic industry and the demands of users. As electronic devices become smaller and lighter, semiconductor packages used for the electronic devices also become smaller and lighter, and in addition, the semiconductor packages require high reliability together with high performance and large capacity. As the semiconductor packages have high performance and high capacity, the power consumption of the semiconductor packages increases. Accordingly, the importance of size reduction, performance improvement of semiconductor packages, and heat dissipation characteristics of semiconductor packages is increasing.

### SUMMARY

The disclosed concepts provide a semiconductor package capable of reducing the possibility of defects and improving the electrical and physical stability of a wire even when the number of vertical stacked layers of semiconductor chips increases.

In addition, the issues to be solved by the technical idea of the disclosed concepts are not limited to those mentioned above, and other issues may be clearly understood by those of ordinary skill in the art from the following descriptions.

According to aspects of the disclosed concepts, there is provided a semiconductor package including a first redistribution substrate, a chip stacked structure including a first sub-stack and a second sub-stack arranged on the first sub-stack, wherein the first sub-stack is arranged apart from the first redistribution substrate above the first redistribution substrate and includes a plurality of semiconductor chips that are stacked, and the second sub-stack includes a plurality of semiconductor chips that are stacked, a second redistribution substrate arranged on the chip stacked structure, a first sub-stack vertical wiring unit including vertical wires configured to connect each of the semiconductor chips constituting the first sub-stack to the first redistribution substrate, and extend to an upper surface of the first redistribution substrate in a vertical direction, a second sub-stack vertical wiring unit including vertical wires configured to connect each of the semiconductor chips constituting the second sub-stack to the second redistribution substrate, and extend to a lower surface of the second redistribution substrate in the vertical direction, and a first sealing material sealing the chip stacked structure, the first sub-stack vertical wiring unit, and the second sub-stack vertical wiring unit between the first redistribution substrate and the second redistribution substrate.

In addition, according to aspects of the disclosed concepts, there is provided a semiconductor package including a first redistribution substrate, a chip stacked structure including a first sub-stack and a second sub-stack arranged on the first sub-stack, wherein the first sub-stack is arranged on the first redistribution substrate and includes a plurality of semiconductor chips stacked on the first sub-stack and the second sub-stack is arranged on the first sub-stack and includes a plurality of semiconductor chips stacked on the second sub-stack, a second redistribution substrate arranged on the chip stacked structure, a first sub-stack vertical wiring unit configured to connect each of the semiconductor chips constituting the first sub-stack except for the semiconductor chip at a lowermost end of the semiconductor chips to the first redistribution substrate, and including vertical wires configured to extend to an upper surface of the first redistribution substrate in a vertical direction, a second sub-stack vertical wiring unit configured to connect each of the semiconductor chips constituting the second sub-stack except for the semiconductor chip at an uppermost end of the semiconductor chips to the second redistribution substrate, and including vertical wires configured to extend to a lower surface of the second redistribution substrate in the vertical direction, and a first sealing material sealing the chip stacked structure, the first sub-stack vertical wiring unit, and the second sub-stack vertical wiring unit between the first redistribution substrate and the second redistribution substrate, wherein a lower surface of the semiconductor chip at a lowermost end of the semiconductor chips constituting the first sub-stack is coplanar with the upper surface of the first redistribution substrate, and an upper surface of the semiconductor chip at an uppermost end of the semiconductor chips constituting the second sub-stack is coplanar with a lower surface of the second redistribution substrate.

Furthermore, according to aspects of the disclosed concepts, there is provided a semiconductor package including a first redistribution substrate, an external connection terminal arranged under a lower surface of the first redistribution substrate, a chip stacked structure including a first sub-stack and a second sub-stack, which are vertically stacked on the first redistribution substrate, a second redistribution substrate arranged on the chip stacked structure, a first sub-stack vertical wiring unit configured to connect the first sub-stack to the first redistribution substrate, a second sub-stack vertical wiring unit configured to connect the second sub-stack to the second redistribution substrate, a first vertical wiring unit configured to be electrically and vertically connected between the first redistribution substrate and the second redistribution substrate, and a first sealing material sealing the chip stacked structure, the first sub-stack vertical wiring unit, and the second sub-stack vertical wiring unit between the first redistribution substrate and the second redistribution substrate, wherein the first sub-stack includes a first semiconductor chip arranged apart from the first redistribution substrate on the first redistribution substrate so that an active surface thereof faces toward the first redistribution substrate, and a second semiconductor chip stacked shifted on the first semiconductor chip in a first horizontal direction so that an active surface thereof faces toward the first redistribution substrate, wherein the second sub-stack includes a third semiconductor chip stacked so that an active surface thereof faces toward the second redistribution substrate and aligned with the first semiconductor chip, and a fourth semiconductor chip stacked so that an active surface thereof faces toward the second redistribution substrate on the third semiconductor chip and aligned to the second semiconductor chip, wherein the first sub-stack vertical wiring unit includes a first sub-stack contact unit in contact with a first lower substrate pad arranged on a lower surface of each of the first semiconductor chip and the second semiconductor chip, and a first sub-stack extension unit extending between the first sub-stack contact unit and the first redistribution substrate, and wherein the second sub-stack vertical wiring unit includes a second sub-stack contact unit in contact with a second upper substrate pad arranged on an upper surface of each of the third semiconductor chip and the fourth semiconductor chip, and a second sub-stack extension unit extending between the second sub-stack contact unit and the second redistribution substrate.

According to aspects of the disclosed concepts, there is provided is a method of manufacturing a semiconductor package including forming a first sub-stack by stacking semiconductor chips on a first carrier substrate, forming a first vertical extension unit on the first carrier substrate and forming a first sub-stack vertical wiring unit on the first sub-stack, forming a first sealing material, forming a first redistribution substrate on the first sealing material, by removing the first carrier substrate and inverting the formed product upside down to attach a second carrier substrate to a lower portion of the first redistribution substrate, forming a second sub-stack on the first sub-stack, forming a second vertical extension unit on the first vertical extension unit, forming a second sub-stack vertical wiring unit on the second sub-stack, forming more of the first sealing material on the first sealing material, and forming a second redistribution substrate on the first sealing material.

According to some embodiments, in the method of manufacturing a semiconductor package, the forming of the first sealing material includes grinding an upper portion of the first sealing material so that end portions of the first vertical extension unit and the first sub-stack vertical wiring unit are exposed, and the forming of the more of the first sealing material on the first sealing material includes grinding an upper portion of the first sealing material so that end portions of the second vertical extension unit and the second sub-stack vertical wiring unit are exposed.

According to some embodiments, a method of manufacturing a semiconductor package further includes arranging a semiconductor device on the second redistribution substrate, forming a second vertical extension unit on the second redistribution substrate, forming a second molding layer on the second redistribution substrate, and forming a metal layer on the second molding layer and the semiconductor device.

According to some embodiments, a first sub-stack includes a plurality of semiconductor chips vertically stacked including active surfaces of the semiconductor chips facing toward a first redistribution substrate, and a second sub-stack includes a plurality of semiconductor chips vertically stacked including the active surfaces of the semiconductor chips facing toward a second redistribution substrate.

According to some embodiments, semiconductor chips of a first sub-stack are stacked in a step-type structure so that a portion of a lower surface of each of the semiconductor chips is exposed, the semiconductor chips of a second sub-stack are stacked in a step-type structure so that a portion of an upper surface of each of the semiconductor chips is exposed, and the semiconductor chip at a lowermost end of the second sub-stack is aligned to the semiconductor chip at a lowermost end of the first sub-stack.

According to some embodiments, a first chip pad is arranged on a lower surface of each of semiconductor chips of a first sub-stack, a second chip pad is arranged on an upper surface of each of the semiconductor chips of a second sub-stack, a first sub-stack vertical wiring unit includes a first sub-stack contact unit in contact with the first chip pad, and a first sub-stack extension unit extending between the first sub-stack contact unit and a first redistribution substrate, and a second sub-stack vertical wiring unit includes a second sub-stack contact unit in contact with the second chip pad, and a second sub-stack extension unit extending between the second sub-stack contact unit and a second redistribution substrate.

According to some embodiments, a semiconductor device is arranged so that at least a portion of a first sub-stack vertically overlaps a portion of a second sub-stack.

According to some embodiments, a semiconductor device includes a logic chip, and a first sub-stack and a second sub-stack include a memory chip.

According to some embodiments, a first contact unit is arranged on an upper end of a first vertical extension unit, the first vertical extension unit extends between the first contact unit and a first redistribution substrate, a second contact unit is arranged between the first contact unit and a lower end of a second vertical extension unit, and the second vertical extension unit extends between the second contact unit and a second redistribution substrate.

According to some embodiments, an upper surface of a first contact unit is arranged at the same vertical level as an upper surface of a first sub-stack, and a lower surface of a second contact unit is arranged at the same vertical level as a lower surface of a second sub-stack.

### BRIEF DESCRIPTION OF THE DRAWINGS

Embodiments of the disclosed concepts will be more clearly understood from the following detailed description taken in conjunction with the accompanying drawings in which:

FIGS. 1A and 1B are respectively a schematic cross-sectional view and a schematic plan view of a semiconductor package, according to embodiments;

FIG. 2 is a schematic cross-sectional view of a semiconductor package according to embodiments;

FIG. 3 is a schematic cross-sectional view of a semiconductor package according to embodiments;

FIG. 4 is a schematic cross-sectional view of a semiconductor package according to embodiments;

FIG. 5 is a schematic cross-sectional view of a semiconductor package according to embodiments;

FIG. 6 is a schematic cross-sectional view of a semiconductor package according to embodiments;

FIG. 7 is a schematic cross-sectional view of a semiconductor package according to embodiments; and

FIGS. 8 through 24 are schematic cross-sectional views showing processes of a method of manufacturing a semiconductor package, according to embodiments.

### DETAILED DESCRIPTION

Hereinafter, embodiments of the disclosed concepts will be described in detail with reference to the accompanying drawings. Identical reference numerals are used for the same constituent elements in the drawings, and duplicate descriptions thereof are omitted.

The disclosed concepts relate to a semiconductor package, and more particularly, to a semiconductor package including a wire.

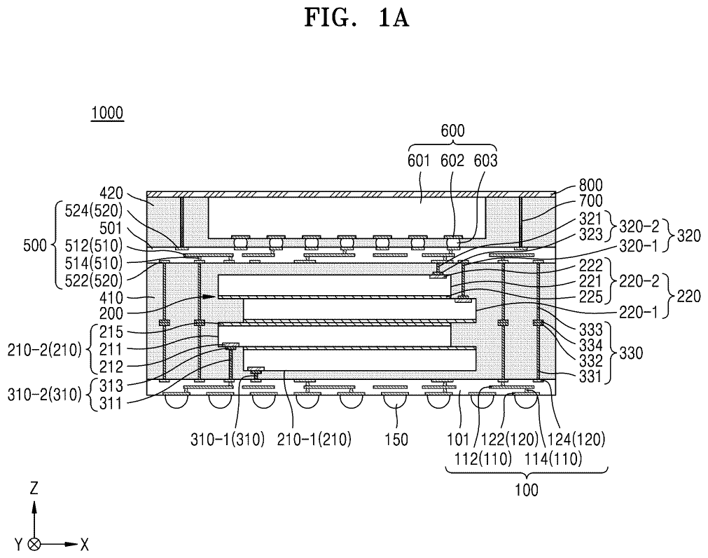

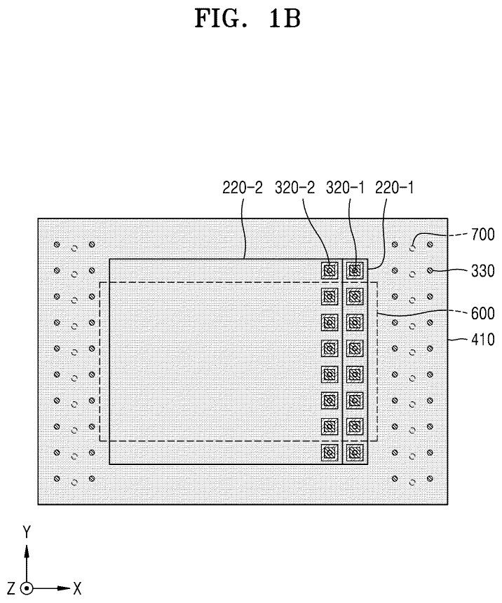

FIGS. 1A and 1B are respectively a schematic cross-sectional view and a schematic plan view of a semiconductor package 1000, according to embodiments. FIG. 1B briefly shows an arrangement of components of the semiconductor package 1000 showing a top-down view of components arranged below the second redistribution substrate 500. In FIG. 1B, positions of a semiconductor device 600 and a second vertical wiring unit 700 on a second redistribution substrate 500 are indicated by dotted lines.

Referring to FIGS. 1A and 1B, the semiconductor package 1000 according to embodiments may include a first redistribution substrate 100, a chip stacked structure 200, a first sub-stack vertical wiring unit 310, a second sub-stack vertical wiring unit 320, a first vertical wiring unit 330, a first sealing material 410, a second sealing material 420, the second redistribution substrate 500, the semiconductor device 600, the second vertical wiring unit 700, and a metal layer 800.

The first redistribution substrate 100 may be arranged below the chip stacked structure 200, the first sub-stack vertical wiring unit 310, the first vertical wiring unit 330, and the first sealing material 410. The first redistribution substrate 100 may redistribute semiconductor chips of the chip stacked structure 200 to an outside region. The first redistribution substrate 100 may include a first body insulating layer 101, a first redistribution pattern 110, and a first substrate pad 120.

The first body insulating layer 101 may include an insulation material, for example, a photo imageable dielectric (PID) resin or a photo imageable polyimide (PIP) resin, and may further include an inorganic filler. However, the material of the first body insulating layer 101 is not limited thereto. For example, the first body insulating layer 101 may also include a polyimide isoindro quirazorindione (PIQ) resin, a polyimide (PI) resin, a polybenzoxazole (PBO) resin, etc.

The first body insulating layer 101 may have a multilayered structure according to a multilayered structure of the first redistribution pattern 110. However, in FIG. 1A, for convenience, the first body insulating layer 101 is illustrated as a single-layer structure. On the other hand, when the first body insulating layer 101 has a multilayered structure, all layers of the first body insulating layer 101 may include the same material, or at least one layer may include a different material.

The first redistribution pattern 110 may include a first redistribution line 112 and a first redistribution via 114. The first redistribution line 112 may be arranged as multiple layers in the first body insulating layer 101. The first redistribution lines 112 arranged on different layers may be connected to each other via the first redistribution via 114.

The first redistribution pattern 110 may perform various functions according to pattern designs. For example, the first redistribution pattern 110 may include a ground pattern, a power pattern, a signal pattern, etc.

The first redistribution line 112 and the first redistribution via 114 may include, for example, copper (Cu). However, the material of the first redistribution line 112 and the first redistribution via 114 is not limited to Cu.

The first substrate pad 120 may include a first lower substrate pad 122 arranged on a lower surface of the first body insulating layer 101 and a first upper substrate pad 124 arranged under an upper surface of the first body insulating layer 101. The first substrate pad 120 may be connected to the first redistribution line 112 via the first redistribution via 114. In embodiments, the first substrate pad 120 may be directly connected to the first redistribution line 112, or a portion of the first redistribution line 112 may be used as the first substrate pad 120. In some embodiments, the first substrate pad 120 may also be treated as a portion of the first redistribution line 112.

Although not illustrated, a protection layer may be arranged under the lower surface and on the upper surface of the first substrate 100, and the first substrate pad 120 may have a structure exposed from the protection layer. An external connection terminal 150 may be arranged on the first lower substrate pad 122. The external connection terminal 150 may connect the semiconductor package 1000 to a package substrate of an outside system, or a main board of an electronic device such as a mobile device. The external connection terminal 150 may include a conductive material, for example, at least one of a solder, tin (Sn), silver (Ag), Cu, and aluminum (Al). On the first upper substrate pad 124, vertical wires of the first sub-stack vertical wiring unit 310 may be connected to vertical wires of the first vertical wiring unit 330.

The chip stacked structure 200 may be arranged on the first redistribution substrate 100, and may include a first sub-stack 210 and a second sub-stack 220, in which a plurality of semiconductor chips are vertically stacked. The first sub-stack 210 and the second sub-stack 220 may include semiconductor chips stacked in opposite directions to each other. For example, first and second semiconductor chips 210-1 and 210-2 may be arranged to include active surfaces thereof facing toward the first substrate 100, and third and fourth semiconductor chips 220-1 and 220-2 of the second sub-stack 220 may be arranged to include active surfaces thereof facing toward the second redistribution substrate 500.

Each of the semiconductor chips 210-1 and 210-2 of the first sub-stack 210 may be the same in terms of size and functionality. Accordingly, hereinafter, the first semiconductor chip 210-1 is mainly described.

The first semiconductor chip 210-1 may include a first chip body layer 211 and a first chip pad 212. The first chip body layer 211 may include a semiconductor substrate, an integrated device layer, a multi-wiring layer, etc. The semiconductor substrate may be based on a semiconductor material such as Si wafer. The device layer may be formed on the semiconductor substrate, and may include various types of devices. For example, the device layer may include a field effect transistor (FET), such as a planar FET and Fin FET, and memory devices, such as a flash memory, dynamic random access memory (RAM) (DRAM), static RAM (SRAM), electrically erasable programmable read-only memory (ROM) (EEPEOM), phase-change RAM (PRAM), magnetoresistive RAM (MRAM), ferroelectric RAM (FeRAM), and resistive RAM (RRAM), logic devices, such as AND, OR, and NOT, and various semiconductor devices, such as large scale integration (LSI), CMOS image sensor (CIS), and micro-electro-mechanical system (MEMS). For example, in the semiconductor package 1000 of embodiments, the first semiconductor chip 210-1 may include a DRAM chip including DRAM devices in a device layer. However, in the semiconductor package 1000 of embodiments, the types of the first semiconductor chip 210-1 is not limited to the DRAM chip.

The first chip pads 212 may be arranged on a lower surface of the first semiconductor chip 210-1. Accordingly, the lower surface of the first semiconductor chip 210-1 may be an active surface, and an upper surface thereof may be an inactive surface. The first chip pads 212 may be arranged biased to any one side portion in a first horizontal direction (X direction). For example, the first chip pads 212 may be arranged, on a left side portion in the first horizontal direction (X direction), and in a second horizontal direction (Y direction). The reason why the first chip pads 212 are arranged biased to one side portion of the corresponding semiconductor chip in the first horizontal direction (X direction) may be that the semiconductor chips are stacked in a step-type structure that rises or descends in the first sub-stack 210 in the first horizontal direction (X direction). For example, in each of the semiconductor chips based on the step-type structure, except for the first semiconductor chip 210-1, only a portion of a left lower surface may be exposed in the first horizontal direction (X direction), and the first chip pads 212 may be arranged on a portion of the exposed lower surface. Meanwhile, although not illustrated, a protection layer may be arranged under the lower surface of the first chip body layer 211, and the first chip pads 212 may be exposed from a chip protection layer.

The first chip pads 212 of each of the first and second semiconductor chips 210-1 and 210-2 of the first sub-stack 210 may be connected to first and second vertical wires 310-1 and 310-2 corresponding to the first sub-stack vertical wiring unit 310. For example, the first chip pads 212 of the first semiconductor chip 210-1 may be connected to the first vertical wires 310-1, and the first chip pads 212 of the second semiconductor chip 210-2 may be connected to the second vertical wires 310-2. Each of the first semiconductor chip 210-1 and the second semiconductor chip 210-2 constituting the first sub-stack 210 may be electrically connected to the first redistribution substrate 100 via the first chip pads 212, the first and second vertical wires 310-1 and 310-2, and the first upper substrate pads 124.

As illustrated in FIG. 1A, in the first sub-stack 210, the first semiconductor chip 210-1 may be attached to the second semiconductor chip 210-2 by using a first adhesive layer 215 on an upper surface of the first semiconductor chip 210-1. For example, the first adhesive layer 215 may include a die attach film (DAF). However, the material of the first adhesive layer 215 is not limited to the DAF. Alternatively, the first semiconductor chip 210-1 may also be attached to the second semiconductor chip 210-2 by using a direct bonding.

The first sub-stack vertical wiring unit 310 may include vertical wires. For example, the first sub-stack vertical wiring unit 310 may include the first vertical wire 310-1 and the second vertical wire 310-2. The first vertical wire 310-1 and the second vertical wire 310-2 may be connected to the first semiconductor chip 210-1 and the second semiconductor chip 210-2 corresponding thereto, respectively. Accordingly, in proportional to a separation distance of the first and second semiconductor chips 210-1 and 210-2 from the first redistribution substrate 100, lengths of the first vertical wire 310-1 and the second vertical wire 310-2 in a vertical direction (Z direction) may be different from each other.

The first vertical wire 310-1 and the second vertical wire 310-2 may have different vertical direction (Z direction) lengths, but may include substantially the same structure and material. Accordingly, when a description is given with the second vertical wire 310-2, the second vertical wire 310-2 may include, for example, gold (Au), Cu, Ag, Al, etc.

The second vertical wire 310-2 may include a first sub-stack extension unit 311 and a first sub-stack contact unit 313. The first sub-stack extension unit 311 may extend downward from the first sub-stack contact unit 313 in the vertical direction (Z direction). The first sub-stack contact unit 313 may be arranged at an upper end of the first sub-stack extension unit 311, and may be coupled to a corresponding semiconductor chip, for example, the first chip pad 212 of the second semiconductor chip 210-2. The first sub-stack contact unit 313 may have a wider area than the first sub-stack extension unit 311 on an X-Y plane.

On the other hand, in a general wire bonding structure, contact units may be formed on both ends of an extension unit. However, in the first sub-stack vertical wiring unit 310 of the semiconductor package 1000 of embodiments, the first sub-stack contact unit 313 may be arranged only at the upper end of the first sub-stack extension unit 311, and a separate contact unit may not be formed at a lower end of the first sub-stack extension unit 311. For example, the lower end of the first sub-stack extension unit 311 may be directly connected to the first upper substrate pad 124 of the first redistribution substrate 100. This type of structure of the second vertical wire 310-2 may be due to the process of forming the vertical wire.

The second sub-stack 220 may be arranged on the first sub-stack 210. Each of the third and fourth semiconductor chips 220-1 and 220-2 constituting the second sub-stack may have the same size and function as the first and second semiconductor chips 210-1 and 210-2 constituting the first sub-stack 210. However, unlike the first and second semiconductor chips 210-1 and 210-2 constituting the first sub-stack 210, the third and fourth semiconductor chips 220-1 and 220-2 constituting the second sub-stack may be arranged so that active surfaces thereof face the second redistribution substrate 500. The description of the third and fourth semiconductor chips 220-1 and 220-2 constituting the second sub-stack 220 is briefly given, the structural characteristics thereof are mainly described, and when one semiconductor chip is described, the third semiconductor chip 220-1 is mainly described.

The third semiconductor chip 220-1 and the fourth semiconductor chip 220-2 of the second sub-stack 220 may be sequentially stacked on an uppermost semiconductor chip of the first sub-stack 210. For example, the third semiconductor chip 220-1 may be stacked on the second semiconductor chip 210-2, and the fourth semiconductor chip 220-2 may be stacked on the third semiconductor chip 220-1. The third semiconductor chip 220-1 and the fourth semiconductor chip 220-2 may be stacked in the opposite direction to the first semiconductor chip 210-1 and the second semiconductor chip 210-2, that is, with the active surfaces of the third semiconductor chip 220-1 and the fourth semiconductor chip 220-2 facing upward.

In the second sub-stack 220, semiconductor chips may be stacked in a step-type structure rising or falling in the first horizontal direction (X direction). In some embodiments, semiconductor chips of the second sub-stack 220 may be stacked in a step-type structure rising in the same direction of semiconductor chips of the first sub-stack 210 (rising to the left side in the first horizontal direction (X direction)). For example, the third semiconductor chip 220-1 may be aligned to completely overlap the first semiconductor chip 210-1 vertically. For example, the fourth semiconductor chip 220-2 may be aligned to completely overlap the second semiconductor chip 210-2 vertically. However, the arrangement of semiconductor chips of the second sub-stack 220 is not limited thereto.

The third semiconductor chip 220-1 may include a second chip body layer 221 and a second chip pad 222. The second chip body layer 221 and the second chip pad 222 may be substantially the same components as the first chip body layer 211 and the first chip pad 212 described with respect to the first sub-stack 210, respectively.

The second chip pads 222 may be arranged on an upper surface of the third semiconductor chip 220-1. Accordingly, an upper surface of the third semiconductor chip 220-1 may be an active surface, and a lower surface thereof may be an inactive surface. The second chip pads 222 may be arranged biased to any one side portion in the first horizontal direction (X direction). For example, the second chip pads 222 may be arranged, at the right-side portion in the first horizontal direction (X direction), in the second horizontal direction (Y direction). In each of the semiconductor chips of the second sub-stack 220, based on the step-type structure, only a portion of the right side of the upper surface may be exposed in the first horizontal direction (X direction), except for the fourth semiconductor chip 220-2 arranged at the uppermost portion, and the second chip pads 222 may be arranged on a portion of the exposed upper surface of the second sub-stack 220. On the other hand, although not illustrated, a protection layer may be arranged on the upper surface of the second chip body layer 221, and the first chip pads 212 may be exposed from the chip protection layer.

The second chip pads 222 of each of the third and fourth semiconductor chips 220-1 and 220-2 of the second sub-stack 220 may be connected to third and fourth vertical wires 320-1 and 320-2 corresponding to the second sub-stack vertical wiring unit 320, respectively. For example, the second chip pads 222 of the third semiconductor chip 220-1 may be connected to the third vertical wires 320-1, and the second chip pads 222 of the fourth semiconductor chip 220-2 may be connected to the fourth vertical wires 320-2. Each of the third semiconductor chip 220-1 and the fourth semiconductor chip 220-2 constituting the second sub-stack 220 may be electrically connected to the second redistribution substrate 500 via the third and fourth vertical wires 320-1 and 320-2 and the second lower substrate pads 522.

In the second sub-stack 220, the fourth semiconductor chip 220-2 may be attached to the third semiconductor chip 220-1 via a second adhesive layer 225 on a lower surface of the fourth semiconductor chip 220-2. The second adhesive layer 225 may be substantially the same component as the first adhesive layer 215. The third semiconductor chip 220-1 may be attached to the second semiconductor chip 210-2 of the first sub-stack 210 via the second adhesive layer 225 on a lower surface of the third semiconductor chip 220-1. In FIG. 1A, all of the first adhesive layers 215 on the second semiconductor chip 210-2 and the second adhesive layers 225 on the third semiconductor chip 220-1 are illustrated, but any one may also be omitted. Semiconductor chips of the second sub-stack 220 may also be attached by using a direct bonding, similar to the semiconductor chips of the first sub-stack 210.

The second sub-stack vertical wiring unit 320 may include vertical wires. For example, the second sub-stack vertical wiring unit 320 may include the third vertical wire 320-1 and the fourth vertical wire 320-2. The third vertical wire 320-1 and the fourth vertical wire 320-2 may be connected to the third semiconductor chip 220-1 and the fourth semiconductor chip 220-2 respectively. Accordingly, in proportional to a separation distance of the third and fourth semiconductor chips 220-1 and 220-2 from the second redistribution substrate 500, lengths of the third vertical wire 320-1 and the fourth vertical wire 320-2 in the vertical direction (Z direction) may be different from each other.

The second sub-stack vertical wiring unit 320 may include a second sub-stack extension unit 321 and a second sub-stack contact unit 323. Components of the second sub-stack vertical wiring unit 320 may corresponding to substantially the same configuration as the components of the first sub-stack vertical wiring unit 310. In the second sub-stack vertical wiring unit 320, the second sub-stack contact unit 323 may be arranged only at the lower end of the second sub-stack extension unit 321, and a separate contact unit may not be formed at the upper end of the second sub-stack extension unit 321. For example, the upper end of the second sub-stack extension unit 321 may be directly connected to the second lower substrate pad 522 of the second redistribution substrate 500.

FIG. 1A illustrates that the chip stacked structure 200 is described to include the first sub-stack 210 including two of the first and second semiconductor chips 210-1 and 210-2 and the second sub-stack 220 including two of the third and fourth semiconductor chips 220-1 and 220-2. However, the total number of semiconductor chips included in the chip stacked structure 200 is not limited to four. For example, each of the first sub-stack 210 and the second sub-stack 220 may include four semiconductor chips. In this case, the semiconductor chip arranged at the lowermost end of the second sub-stack 220 may be aligned to overlap completely and vertically the semiconductor chip arranged at the lowermost end of the first sub-stack 210, and the semiconductor chip arranged at the uppermost end of the second sub-stack 220 may be aligned to overlap completely and vertically the semiconductor chip arranged at the uppermost end of the first sub-stack 210. However, the number of semiconductor chips included in the first sub-stack 210 and the second sub-stack 220 is not limited thereto, and may be variously changed within a scope that one of ordinary skill in the art may understand. In addition, the arrangement of semiconductor chips of each of the first sub-stack 210 and the second sub-stack 220 may be a stacked step-type structure, may be variously modified so that the first sub-stack 210 is connected to the first redistribution substrate 100 via the first sub-stack vertical wiring unit 310, and the second sub-stack 220 is connected to the second redistribution substrate 500 via the second sub-stack vertical wiring unit 320.

The first vertical wiring unit 330 may be arranged apart from the chip stacked structure 200 on the first redistribution substrate 100. The first vertical wiring unit 330 may electrically connect between the first redistribution substrate 100 and the second redistribution substrate 500.

The first vertical wiring unit 330 may include a first vertical extension unit 331 formed at a height corresponding to that of the first sub-stack 210, a first contact unit 332, a second vertical extension unit 333 formed at a height corresponding to that of the second sub-stack 220 and a second contact unit 334.

The first contact unit 332 may be arranged on the same vertical level as the upper surface of the first sub-stack 210. For example, the upper surface of the first contact unit 332 may be arranged on the upper surface of the second semiconductor chip 210-2 arranged at the uppermost end of semiconductor chips of the first sub-stack 210, or may be arranged on the same vertical level as the upper surface of the first adhesive layer 215 arranged on the second semiconductor chip 210-2. The first vertical extension unit 331 may extend between the first redistribution substrate 100 and the first contact unit 332 in the vertical direction (Z direction). The upper end of the first vertical extension unit 331 may be connected to the first contact unit 332, and the lower end of the first vertical extension unit 331 may be directly connected to the first upper substrate pad 124 of the first redistribution substrate 100.

The second contact unit 334 may be arranged on the first contact unit 332. The second contact unit 334 may be arranged on the same vertical level as the lower surface of the second sub-stack 220. For example, the lower surface of the second contact unit 334 may be arranged on the same vertical level as the lower surface of the third semiconductor chip 220-1 located at the lowermost end of the semiconductor chips of the second sub-stack 220, or may be arranged on the same vertical level as the lower surface of the second adhesive layer 225 arranged under the third semiconductor chip 220-1. The second vertical extension unit 333 may extend between the second redistribution substrate 500 and the second contact unit 334 in the vertical direction (Z direction). A lower end of the second vertical extension unit 333 may be connected to the second contact unit 334, and an upper end of the second vertical extension unit 333 may be directly connected to the second lower substrate pad 522 of the second redistribution substrate 500. The second vertical extension unit 333 may be aligned to vertically overlap the first vertical extension unit 331.

The first sealing material 410 may be arranged between the first redistribution substrate 100 and the second redistribution substrate 500, and may seal the chip stacked structure 200, the first sub-stack vertical wiring unit 310, the second sub-stack vertical wiring unit 320, and the first vertical wiring unit 330. The first sealing material 410 may prevent the semiconductor chips of the chip stacked structure 200 from being contaminated by external foreign substances. In addition, the first sealing material 410 may protect the semiconductor package 1000 from external impact.

The first sealing material 410 may include an insulating material, for example, a thermosetting resin such as an epoxy resin, a thermoplastic resin such as polyimide, or a resin including a reinforcing material such as an inorganic filler. For example, the first sealing material 410 may include Ajinomoto build-up film (ABF), flame retardant-4 (FR-4), a bismaleimide triazine (BT) resin. In addition, the first sealing material 410 may include a molding material such as epoxy molding compound (EMC), or a photosensitive material such as photoimageable encapsulant (PIE). However, the material of the first sealing material 410 is not limited thereto.

The second redistribution substrate 500 may be arranged on the first sealing material 410. The second redistribution substrate 500 may redistribute and electrically connect the semiconductor device 600 arranged thereon and the chip stacked structure 200 arranged thereunder. The second redistribution substrate 500 may include a second body insulating layer 501, a second redistribution pattern 510, and a second substrate pad 520. Each of the components of the second redistribution substrate 500 may be substantially the same as the components of the first redistribution substrate 100.

The second redistribution pattern 510 may include a second wiring line 512 and a second redistribution via 514. The second substrate pad 520 may include a second lower substrate pad 522 arranged on the lower surface of the second body insulating layer 501 and a second upper substrate pad 524 arranged on the upper surface of the second body insulating layer 501. The second vertical extension unit 333 of the first vertical wiring unit 330 and the second sub-stack extension unit 321 of the second sub-stack vertical wiring unit 320 may be connected to the second lower substrate pad 522. The semiconductor device 600 and the second vertical wiring unit 700 may be connected to the second upper substrate pad 524. Although not illustrated, a protection layer may be arranged under the lower surface and on the upper surface of the second redistribution substrate 500, and the second substrate pad 520 may have a structure exposed from the protection layer.

The semiconductor device 600 may be mounted on the second redistribution substrate 500. The semiconductor device 600 may include a chip body 601, a chip pad 602, and a chip connection terminal 603.

The semiconductor device 600 may include a non-memory device. The chip body 601 may include a logic chip. In this case, the logic chip may include, for example, a system on chip, a central processing unit (CPU) chip, a graphics processing unit (GPU) chip, or an application processor (AP) chip. The semiconductor device 600 may execute applications supported by the semiconductor package 1000 by using the chip stacked structure 200. For example, the semiconductor device 600 may execute specialized computations by using at least one processor of a CPU, an application processor (AP), a GPU, a neural processing unit (NPU), a tensor processing unit (TPU), a vision processing unit (VPU), an image signal processing unit (ISP), and a digital signal processor (DSP).

In addition, the chip pad 602 may be used to electrically connect the semiconductor device 600 to other components. The chip pad 602 may include a conductive material, for example, Cu, Al, Ag, Au, tungsten (W), titanium (Ti), or a combination thereof. The chip connection terminal 603 may be attached to the chip pad 602, and may electrically connect the semiconductor device 600 to the second redistribution substrate 500.

The chip connection terminal 603 may include, for example, a solder ball. According to embodiments, the chip connection terminal 603 may include tin (Sn), indium (In), bismuth (Bi), antimony (Sb), Cu, Ag, zinc (Zn), lead (Pb), and/or an alloy thereof. For example, the chip connection terminal 603 may have a spherical or ball shape including an alloy including Sn (for example, Sn—Ag—Cu). The chip connection terminal 603 may be configured to electrically connect the second redistribution substrate 500 to the chip body 601.

According to some embodiments, the semiconductor device 600 may be arranged to vertically overlap at least a portion of the chip stacked structure 200. Accordingly, heat generated by the chip stacked structure 200 may be transferred to the metal layer 800 via the semiconductor device 600, and thus the heat dissipation function may be improved.

In some embodiments, a semiconductor package instead of the semiconductor device 600 may also be arranged on the second redistribution substrate 500. In this case, the semiconductor package 1000 may be implemented as a package-on-package type package.

The second vertical wiring unit 700 may be arranged apart from the semiconductor device 600 on the second redistribution substrate 500. Referring to FIG. 1B, for example, the second vertical wiring unit 700 may be apart from the semiconductor device 600 in the first horizontal direction (X direction) and arranged in the second direction (Y direction).

The second vertical wiring unit 700 may electrically connect between the metal layer 800 and the second redistribution substrate 500, and by forming a ground path of the semiconductor device 600 to prevent a voltage transient phenomenon due to electrostatic discharge (ESD), may protect the semiconductor device 600.

The metal layer 800 may be arranged on the semiconductor device 600. The metal layer 800 may be arranged to cover an upper surface of the semiconductor device 600 with a thin metal plate. For example, the metal layer 800 may have the same size as the second redistribution substrate 500 on the X-Y plane. The metal layer 800 may be connected to the second vertical wiring unit 700 to perform a grounding role while protecting the semiconductor device 600.

The metal layer 800 may also perform a heat dissipation function. The metal layer 800 may effectively disperse heat to receive from the semiconductor device 600 and prevent overheating of the semiconductor package 1000. In addition, because the metal layer 800 may also be utilized as a shielding layer, the metal layer 800 may suppress electromagnetic interference (EMI) and cross-talk generated inside and outside a package.

For example, the metal layer 800 may include Cu, Al, Ag, or the like, but is not limited thereto.

The second sealing material 420 may be arranged between the second redistribution substrate 500 and the metal layer 800, and may seal the semiconductor device 600 and the second vertical wiring unit 700. The second sealing material 420 may prevent the semiconductor device 600 from being contaminated by external foreign substances. In addition, the second sealing material 420 may protect the semiconductor package 1000 from external impact.

In the semiconductor package 1000 of the present embodiment, by arranging the first sub-stack vertical wiring unit 310 between the first redistribution substrate 100 and the first sub-stack 210, and arranging the second sub-stack vertical wiring unit 320 between the second redistribution substrate 500 and the second sub-stack 220, the overall size of the semiconductor package 1000 may be reduced. In addition, because the first sub-stack 210 and the second sub-stack 220 are stacked in opposite directions, the length of vertical wires may be reduced, and thus the electrical and physical stability of wires may be improved.

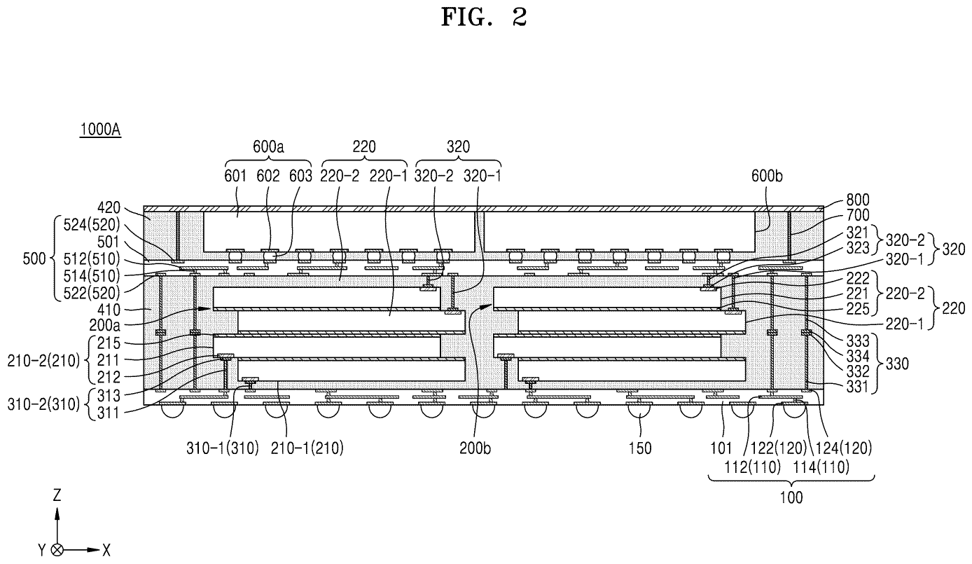

FIG. 2 is a schematic cross-sectional view of a semiconductor package 1000A according to embodiments. The semiconductor package 1000A illustrated in FIG. 2 may be almost the same as or similar to the semiconductor package 1000 illustrated in FIGS. 1A and 1B, except for the number of the chip stacked structures 200 and the semiconductor devices 600. Accordingly, descriptions of the components already given with reference to FIGS. 1A and 1B are omitted or simplified below.

Referring to FIG. 2, the semiconductor package 1000A according to embodiments may include the first redistribution substrate 100, a first chip stacked structure 200a, a second chip stacked structure 200b, the first sub-stack vertical wiring unit 310, the second sub-stack vertical wiring unit 320, the first vertical wiring unit 330, the first sealing material 410, the second sealing material 420, the second redistribution substrate 500, a first semiconductor device 600a, a second semiconductor device 600b, the second vertical wiring unit 700, and the metal layer 800.

The first chip stacked structure 200a and the second chip stacked structure 200b may be horizontally arranged apart from each other on the first redistribution substrate 100. The first semiconductor device 600a and the second semiconductor device 600b may be horizontally arranged apart from each other on the second redistribution substrate 500. The first chip stacked structure 200a and the second chip stacked structure 200b may have the same configuration as the chip stacked structure 200 of the semiconductor package 1000 of FIG. 1A. The first semiconductor device 600a and the second semiconductor device 600b may have the same configuration as the semiconductor device 600 of the semiconductor package 1000 in FIG. 1A. The semiconductor package 1000A may also include a plurality of chip stacked structures and semiconductor devices as necessary.

In this case, a portion of the first and second semiconductor devices 600a and 600b may be arranged to vertically overlap the first and second chip stacked structures 200a and 200b, respectively, and this arrangement may be advantageous from a heat dissipation aspect.

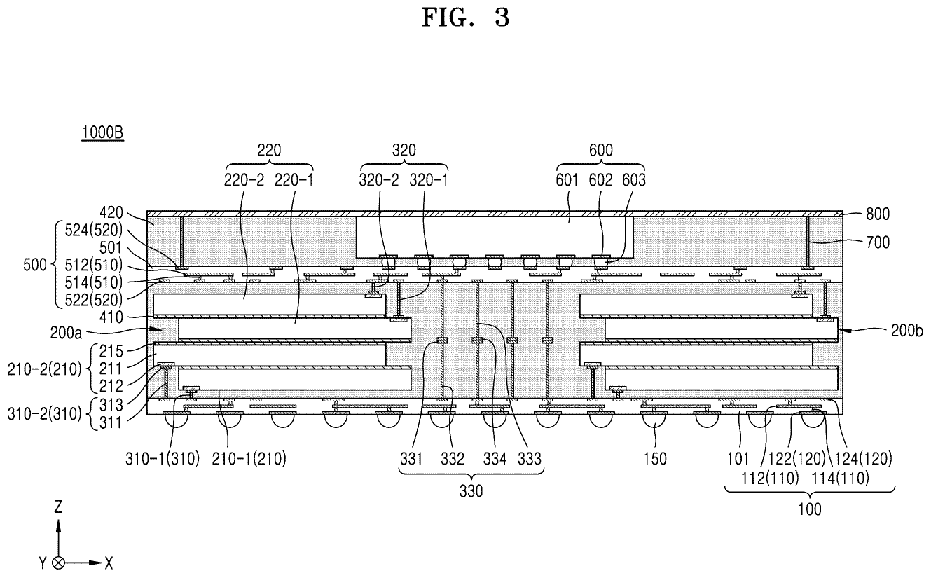

FIG. 63 is a schematic cross-sectional view of a semiconductor package 1000B according to embodiments. The semiconductor package 1000B illustrated in FIG. 3 may be almost the same as or similar to the semiconductor package 1000A illustrated in FIG. 2, except the arrangement of the semiconductor device 600. Accordingly, descriptions of the components already given with reference to FIG. 2 are omitted or simplified below.

Referring to FIG. 3, the semiconductor package 1000B according to embodiments may include the first redistribution substrate 100, a first chip stacked structure 200a, the second chip stacked structure 200b, the first sub-stack vertical wiring unit 310, the second sub-stack vertical wiring unit 320, the first vertical wiring unit 330, the first sealing material 410, the second sealing material 420, the second redistribution substrate 500, the semiconductor device 600, the second vertical wiring unit 700, and the metal layer 800.

The semiconductor package 1000B may include the number of semiconductor devices 600 that is different from the number of chip-stacked structures. For example, the semiconductor package 1000B may include two of the first and second chip stacked structures 200a and 200b and one semiconductor device 600. In this case, the semiconductor device 600 may be arranged to partially and vertically overlap each of the first chip stacked structure 200a and the second chip stacked structure 200b.

In addition, unlike the semiconductor package 1000 of FIG. 1A, the first vertical wiring unit 330 may be arranged between the first chip stacked structure 200a and the second chip stacked structure 200b.

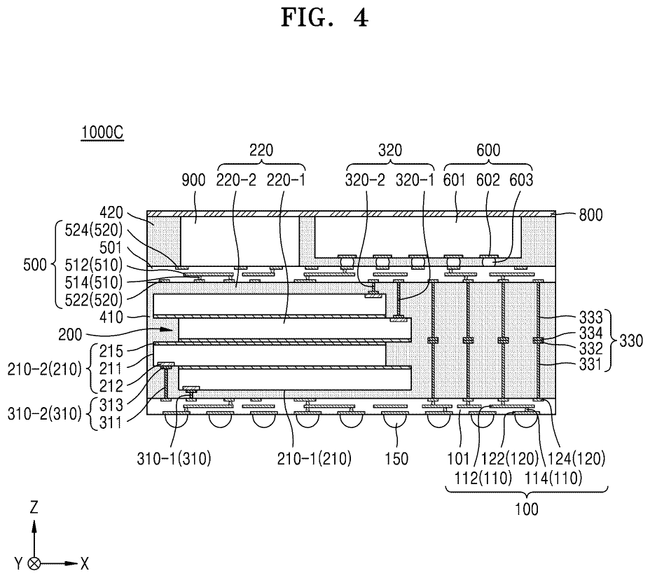

FIG. 4 is a schematic cross-sectional view of a semiconductor package 1000C according to embodiments. The semiconductor package 1000C illustrated in FIG. 4 may be almost the same as or similar to the semiconductor package 1000 illustrated in FIGS. 1A and 1B, except the arrangement of a dummy chip 900. Accordingly, descriptions of the components already given with reference to FIGS. 1A and 1B are omitted or simplified below.

Referring to FIG. 4, the semiconductor package 1000C according to embodiments may include the first redistribution substrate 100, the chip stacked structure 200, the first sub-stack vertical wiring unit 310, the second sub-stack vertical wiring unit 320, the first sealing material 410, the second sealing material 420, the second redistribution substrate 500, the semiconductor device 600, the metal layer 800, and the dummy chip 900.

The dummy chip 900 may be arranged on the second redistribution substrate 500. The dummy chip 900 may be arranged apart from the semiconductor device 600 on the second redistribution substrate 500 in the first horizontal direction (X direction). The dummy chip 900 may include, for example, a semiconductor material such as Si. For example, at least a portion of the dummy chip 900 may be arranged to vertically overlap the chip stacked structure 200 to improve the heat dissipation function of the semiconductor package 1000C.

Although FIG. 4 illustrates that a second vertical wiring unit is not included between the second redistribution substrate 500 and the metal layer 800, embodiments is not limited thereto, and the semiconductor package 1000C may also further include a second vertical wiring unit extending between the second redistribution substrate 500 and the metal layer 800.

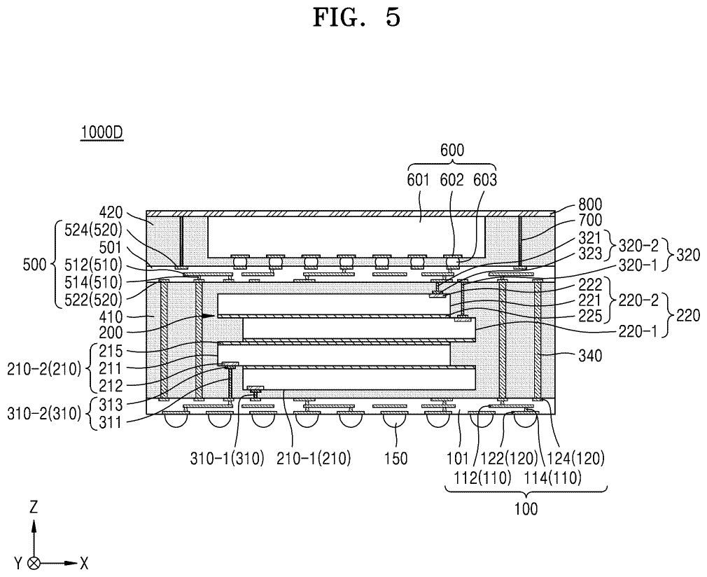

FIG. 5 is a schematic cross-sectional view of a semiconductor package 1000D according to embodiments. The semiconductor package 1000D illustrated in FIG. 5 may be almost the same as or similar to the semiconductor package 1000 illustrated in FIGS. 1A and 1B, except the arrangement of a conductive post 340. Accordingly, descriptions of the components already given with reference to FIGS. 1A and 1B are omitted or simplified below.

Referring to FIG. 5, the semiconductor package 1000D according to embodiments may include the first redistribution substrate 100, the chip stacked structure 200, the first sub-stack vertical wiring unit 310, the second sub-stack vertical wiring unit 320, the conductive post 340, the first sealing material 410, the second sealing material 420, the second redistribution substrate 500, the semiconductor device 600, the second vertical wiring unit 700, and the metal layer 800.

The conductive post 340 may extend and be arranged between the first redistribution substrate 100 and the second redistribution substrate 500. The conductive post 340 may replace the first vertical wiring unit 330 in FIG. 1A. The conductive post 340 may be arranged apart from the chip stacked structure 200, and may electrically connect the first redistribution substrate 100 to the second redistribution substrate 500. For example, the conductive post 340 may include Cu. However, the material of the conductive post 340 is not limited thereto.

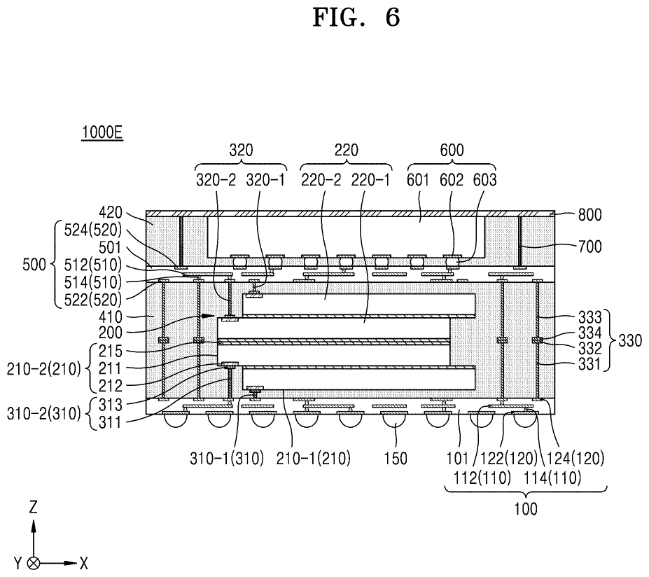

FIG. 6 is a schematic cross-sectional view of a semiconductor package 1000E according to embodiments. The semiconductor package 1000E illustrated in FIG. 6 may be almost the same as or similar to the semiconductor package 1000 illustrated in FIGS. 1A and 1B, except the arrangement of the second sub-stack 220. Accordingly, descriptions of the components already given with reference to FIGS. 1A and 1B are omitted or simplified below.

In the second sub-stack 220, semiconductor chips may be stacked in a step-type structure rising or falling in the first horizontal direction (X direction). In some embodiments, semiconductor chips of the second sub-stack 220 may be stacked in a step-type structure rising in the opposite direction of semiconductor chips of the first sub-stack 210 (rising to the right side in the first horizontal direction (X direction)). In this case, for example, the third semiconductor chip 220-1 may be aligned to completely and vertically overlap the second semiconductor chip 210-2. For example, the fourth semiconductor chip 220-2 may be aligned to completely and vertically overlap the first semiconductor chip 210-1.

In this case, the second chip pads 222 may be arranged biased to the left portion on the upper surface of the third semiconductor chip 220-1 and the upper surface of the fourth semiconductor chip 220-2 in the first horizontal direction (X direction). For example, the second chip pads 222 may be arranged, at the left side portion in the first horizontal direction (X direction), in the second horizontal direction (Y direction).

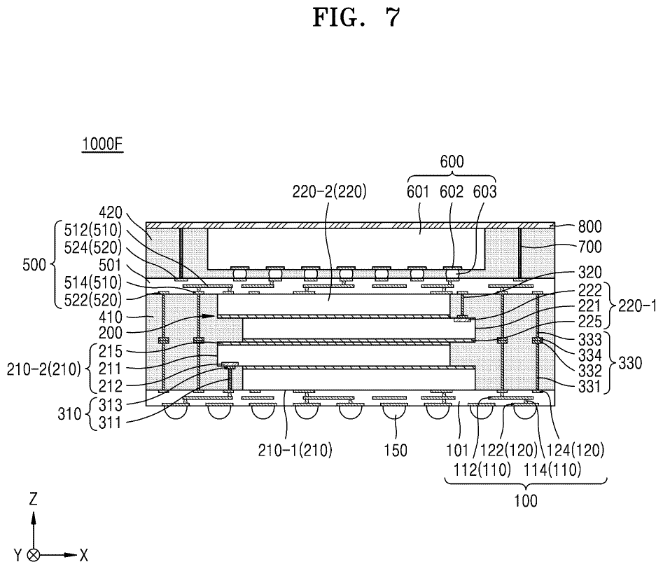

FIG. 7 is a schematic cross-sectional view of a semiconductor package 1000F according to embodiments. The semiconductor package 1000F illustrated in FIG. 7 may be almost the same as or similar to the semiconductor package 1000 illustrated in FIGS. 1A and 1B, except the arrangement of the chip stacked structure 200. Accordingly, descriptions of the components already given with reference to FIGS. 1A and 1B are omitted or simplified below.

Referring to FIG. 7, in the chip stacked structure 200, the first semiconductor chip 210-1 at the lowermost end of the first sub-stack 210 may be directly coupled to the first redistribution substrate 100, and the second semiconductor chip 220-2 at the uppermost end of the second sub-stack 220 may be directly coupled to the second redistribution substrate 500. In other words, the remaining semiconductor chips, except for the semiconductor chip at the lowermost end among the semiconductor chips constituting the first sub-stack 210, may be connected to the first redistribution substrate 100 by using the first sub-stack vertical wiring unit 310, and the remaining semiconductor chips, except for the uppermost semiconductor chip among the semiconductor chips constituting the second sub-stack 220, may be connected to the second redistribution substrate 500 by using the second sub-stack vertical wiring unit 320.

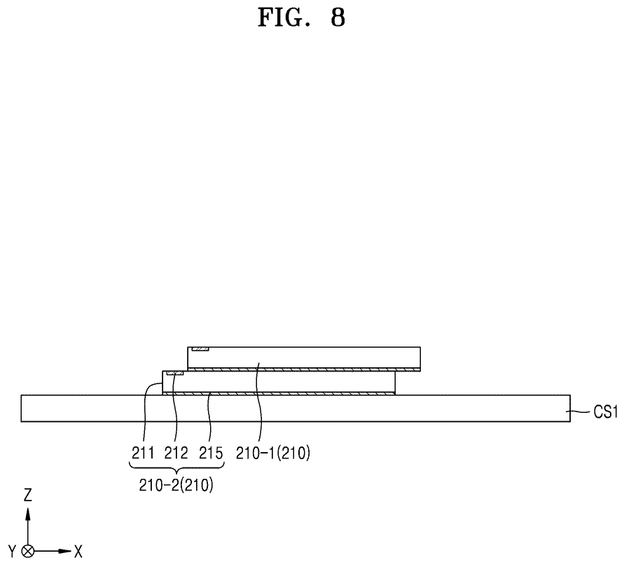

FIGS. 8 through 24 are schematic cross-sectional views of processes of a method of manufacturing the semiconductor package 1000, according to embodiments.

Referring to FIG. 8, firstly, the second semiconductor chip 210-2 may be attached to a first carrier substrate CS1. The second semiconductor chip 210-2 may correspond to an uppermost semiconductor chip forming the first sub-stack 210. In addition, the second semiconductor chip 210-2 may correspond to a structure in which the upper and lower portions are inverted compared to the second semiconductor chip 210-2 of the chip stacked structure 200 in FIG. 1A. Accordingly, in FIG. 8, the upper surface of the second semiconductor chip 210-2 may be an active surface, and the lower surface thereof may be an inactive surface. In addition, the first chip pads 212 may be arranged on the upper surface of the second semiconductor chip 210-2, and may be arranged, on the right side in the first horizontal direction (X direction), in the second horizontal direction (Y direction).

The first semiconductor chip 210-1 may be arranged on the second semiconductor chip 210-2 to be shifted in the first horizontal direction (X direction) to form the first sub-stack 210 in the step-type structure. The second semiconductor chip 210-2 and the first semiconductor chip 210-1 may be coupled to each other by using the first adhesive layer 215. In this case, the first adhesive layer 215 may include, for example, a DAF.

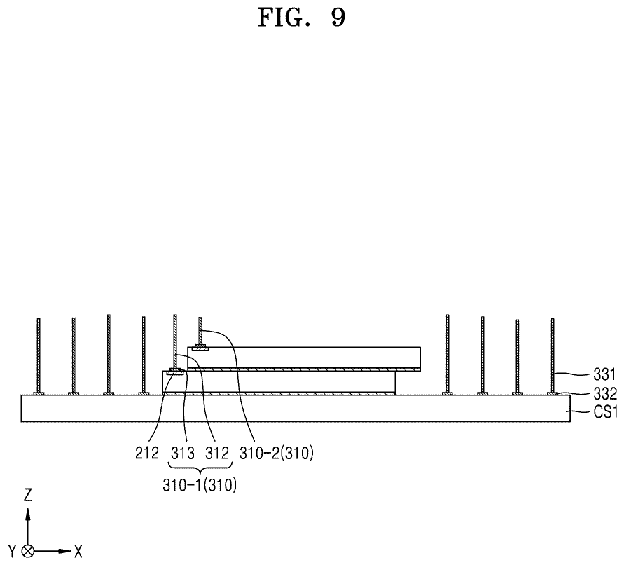

Referring to FIG. 9, after the first sub-stack 210 is configured, the first sub-stack vertical wiring unit 310 and the first vertical wiring unit 330 may be formed on the first chip pads 212. The second vertical wires 310-2 may be formed on the first chip pad 212 of the second semiconductor chip 210-2, and the first vertical wires 310-1 may be formed on the first chip pad 212 of the first semiconductor chip 210-1. The first vertical wiring unit 330, including the first vertical wire unit 331 and the first contact unit 332, may be formed, on the first carrier substrate CS1, to be apart from the first sub-stack 210 in a horizontal direction (X direction and/or Y direction).

To briefly explain the formation of a vertical wire, one end of a wire may be bonded to the first chip pad 212 by using a wire bonding machine. The wire may include a metal such as Au, Ag, Cu, and platinum (Pt), or an alloy thereof, which can be welded to the first chip pad 212 by using an ultrasonic wave energy and/or heat. Next, by using a wire bonding machine, the other end of the wire may be pulled from the bottom to the top in a direction away from the first carrier substrate CS1, for example, in the vertical direction (Z direction). Thereafter, when the other end of the wire extends to a desired position, the other end of the wire may be cut. By using a method in this manner, the vertical wire may be formed. On the other hand, a lower end of the vertical wire may be bonded to the first chip pad 212 to form a first sub-stack contact unit 313.

When the first contact unit 332 is formed on the first carrier substrate CS1, and the wire is pulled in a direction away from the first carrier substrate CS1, for example, from the bottom to the top in the vertical direction (Z direction) up to the desired position, the wire may be cut to form the first vertical extension unit 331.

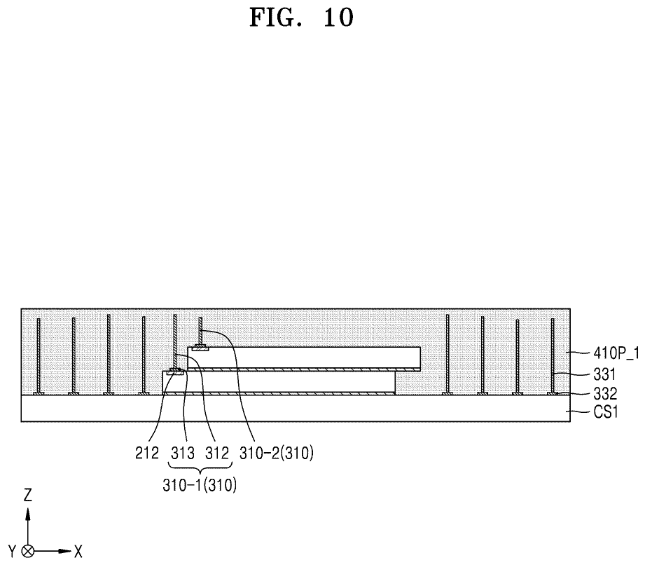

Referring to FIG. 10, a first lower panel sealing material 410P_1 may be formed. the first lower panel sealing material 410P_1 may cover the upper surface of the first sub-stack 210, for example, an upper surface of the first semiconductor chip 210-1. In addition, the first lower panel sealing material 410P_1 may cover the upper ends of the vertical wires of the first sub-stack vertical wiring unit 310 and the first vertical extension unit 331. The first lower panel sealing material 410P_1 may include, for example, EMC. However, the material of the first lower panel sealing material 410P_1 is not limited thereto.

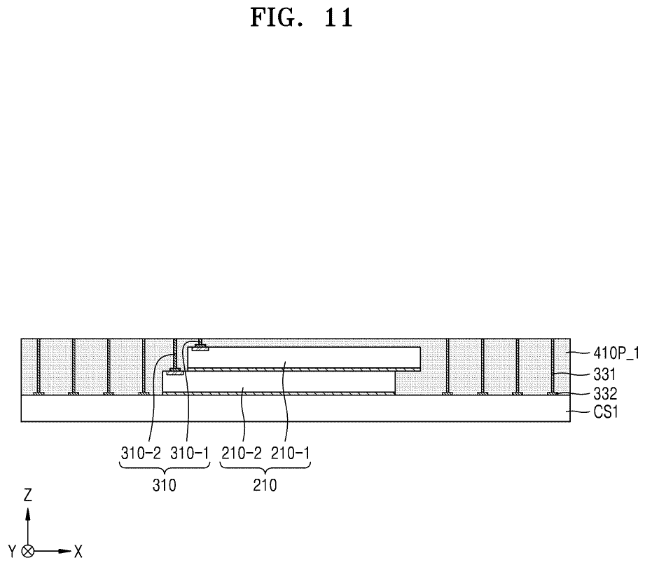

Referring to FIG. 11, after the first lower panel sealing material 410P_1 is formed, an upper portion of the first lower panel sealing material 410P_1 may be removed by using a grinding process operation. By using the grinding process operation, the thickness of the first lower panel sealing material 410P_1 may be reduced, and the first lower panel sealing material 410P_1 may become a lower portion of the first sealing material 410.

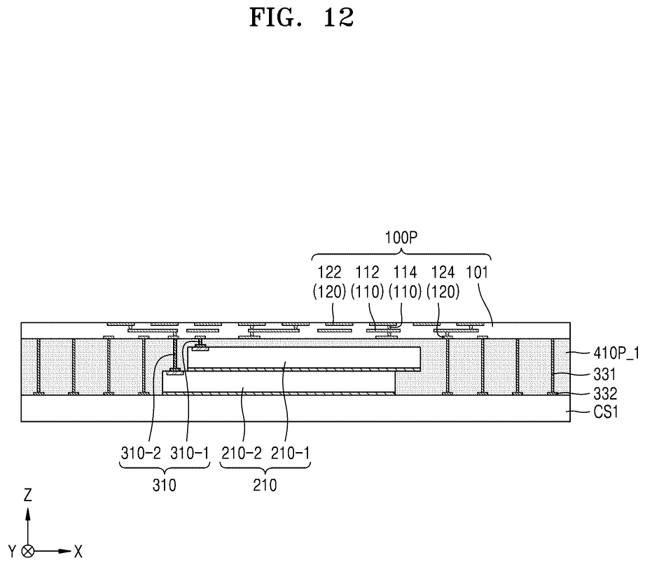

Referring to FIG. 12, the first lower panel sealing material 410P_1 may be formed on a first panel redistribution substrate 100P. The first panel redistribution substrate 100P may include the first body insulating layer 101, the first wiring pattern 110, and the first substrate pad 120. The first panel redistribution substrate 100P may include a plurality of first redistribution substrates 100 before separation. Description of each of the plurality of first redistribution substrates 100 of the first panel redistribution substrate 100P may be the same as that of the first redistribution substrate 100 of the semiconductor package 1000 of FIG. 1A. On the other hand, the vertical wires of the first vertical extension unit 331 may be connected to the first substrate pad 120, of the first redistribution substrate 100, which corresponds to the vertical wires.

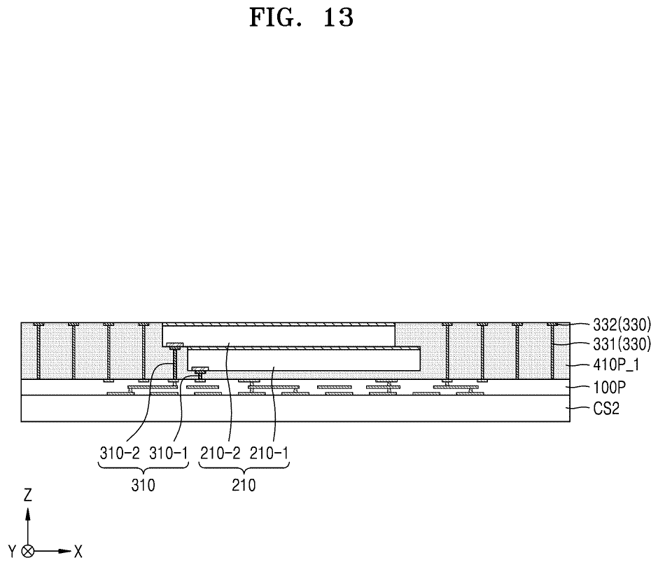

Referring to FIG. 13, after the first carrier substrate CS1 is separated from the resultant product of FIG. 12, and the top and bottom of the first carrier substrate CS1 is inverted, the first panel redistribution substrate 100P may be attached to a second carrier substrate CS2.

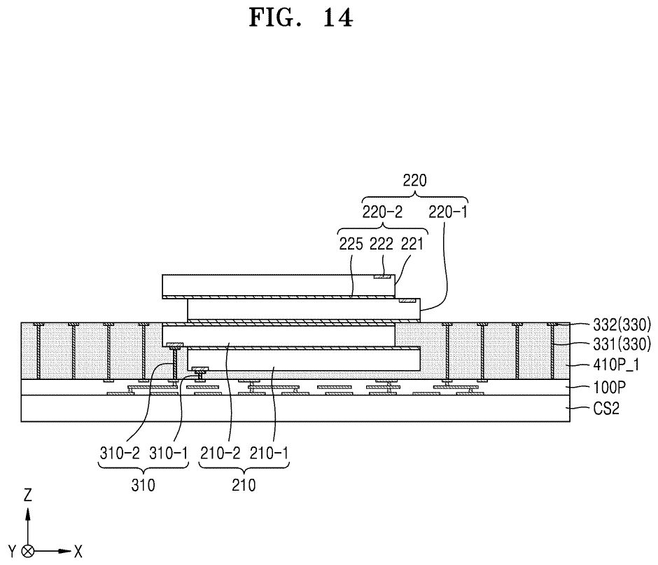

Referring to FIG. 14, thereafter, the second sub-stack 220 may be formed on the first sub-stack 210. For example, the third semiconductor chip 220-1 may be attached onto the second semiconductor chip 210-2. In this case, the active surface of the third semiconductor chip 220-1 may be arranged to face upward. The fourth semiconductor chips 220-2 may be stacked on the third semiconductor chip 220-1.

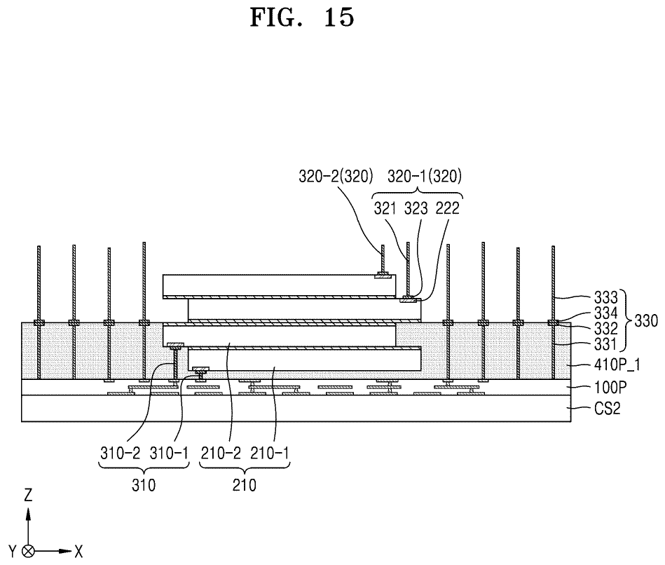

Referring to FIG. 15, after the second sub-stack 220 is configured, the second sub-stack vertical wiring unit 320 including third vertical wires 320-1 and fourth vertical wires 320-2 on the second chip pads 222, and the second vertical extension unit 333 and the second contact unit 334 constituting the first vertical wiring unit 330 may be formed.

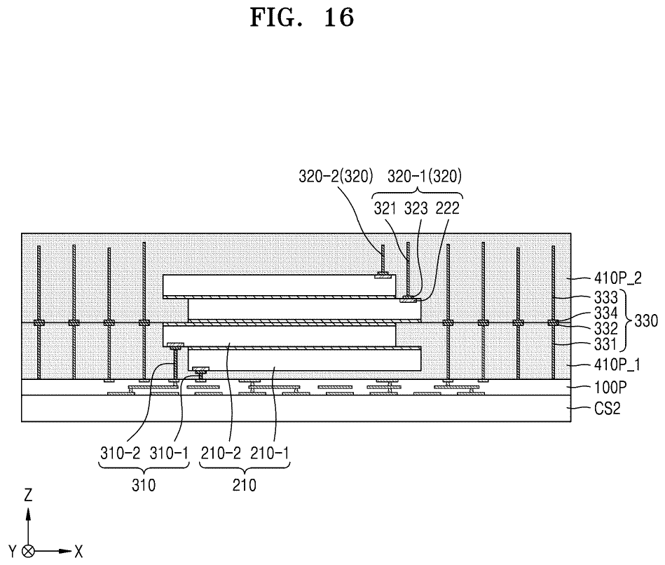

Referring to FIG. 16, a second lower panel sealing material 410P_2 may be formed. The second lower panel sealing material 410P_2 may cover the under surface of the chip stacked structure 200, for example, the upper surface of the fourth semiconductor chip 220-2. In addition, the second lower panel sealing material 410P_2 may cover the upper ends of the vertical wires of the second sub-stack vertical wiring unit 320 and the second vertical extension unit 333. The second lower panel sealing material 410P_2 may be arranged on the first lower panel sealing material 410P_1. The second lower panel sealing material 410P_2 may include the same material as the first lower panel sealing material 410P_1. For convenience, the first lower panel sealing material 410P_1 and the second lower panel sealing material 410P_2 are illustrated as being differentiated from each other, but the first lower panel sealing material 410P_1 and the second lower panel sealing material 410P_2 may be formed in one body without a differentiated interface therebetween. Both the first lower panel sealing material 410P_1 and the second lower panel sealing material 410P_2 may be collectively referred to as a first panel sealing material 410P.

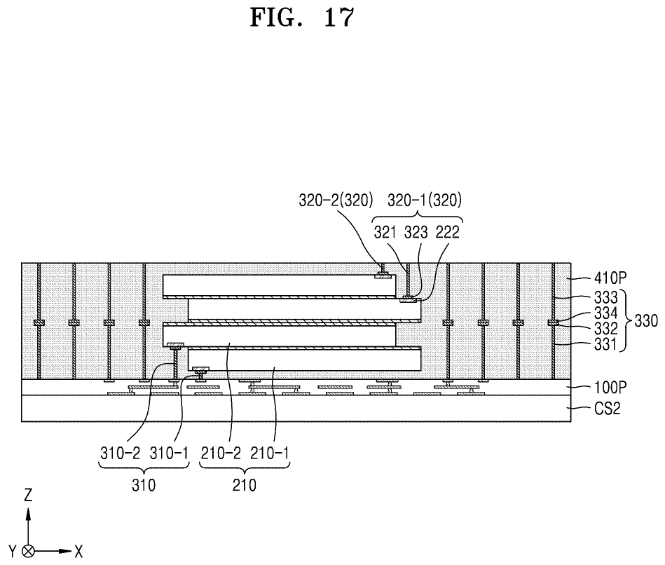

Referring to FIG. 17, after the first panel sealing material 410P is formed, an upper portion of the first panel sealing material 410P may be removed by using a grinding process operation. By using the grinding process operation, the thickness of the first panel sealing material 410P may be reduced. In a subsequent process, the first panel sealing material 410P may become the first sealing material 410 by using a sawing process operation.

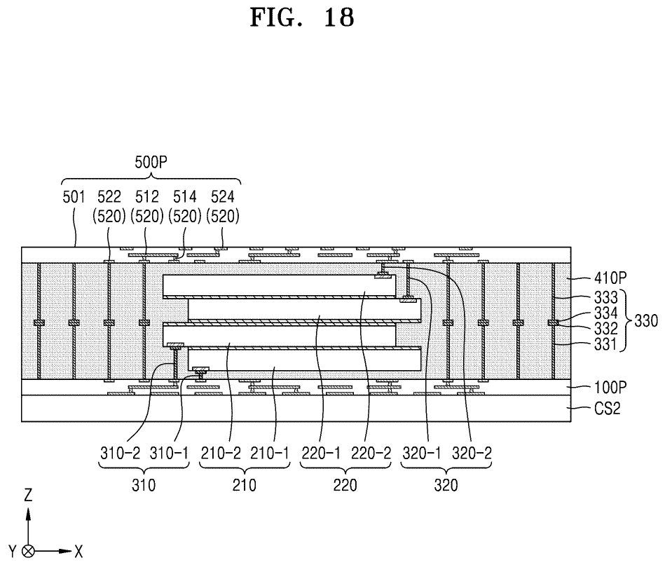

Referring to FIG. 18, a second panel redistribution substrate 500P may be formed on the first panel sealing material 410P. The second panel redistribution substrate 500P may include the second body insulating layer 501, the second redistribution pattern 510, and a substrate pad 520. The second panel redistribution substrate 500P may be formed so that the second sub-stack vertical wiring unit 320 is connected to the second lower substrate pad 522.

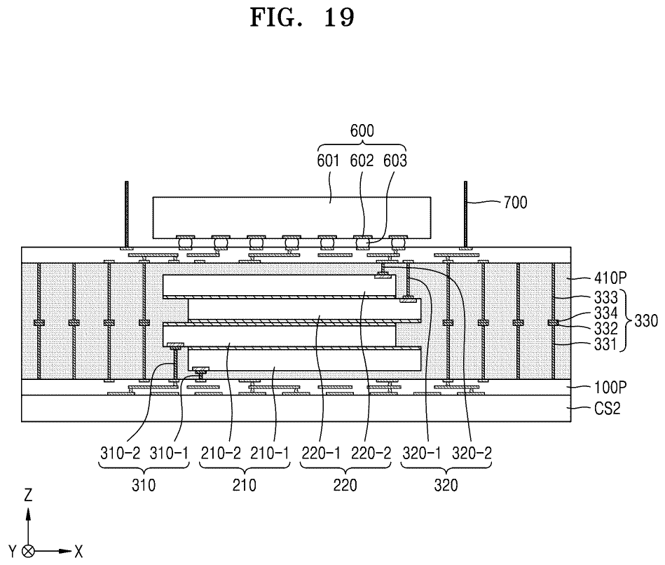

Referring to FIG. 19, the semiconductor device 600 may be arranged on the second panel redistribution substrate 500P. The semiconductor device 600 may be arranged so that the chip connection terminal 603 is on the second upper substrate pad 524 of the second panel redistribution substrate 500P. The second vertical wiring unit 700 may be formed on the second panel redistribution substrate 500P to be horizontally apart from the semiconductor device 600.

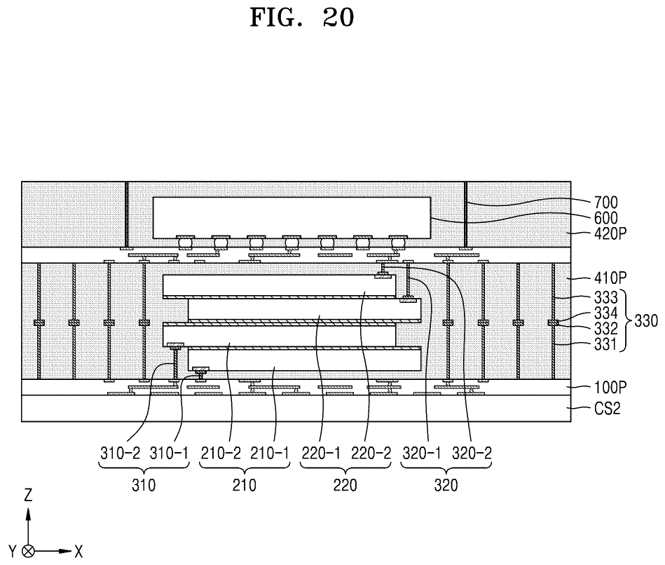

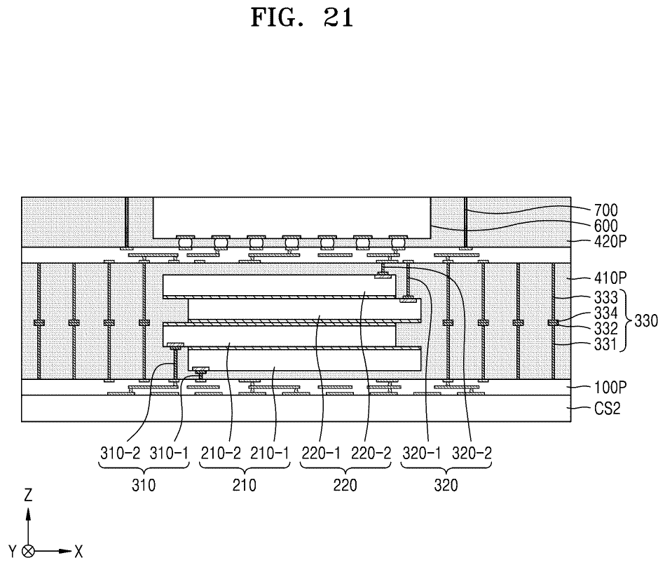

Referring to FIGS. 20 and 21, an upper portion of a second panel sealing material 420P may be removed by using a grinding process operation after the second panel sealing material 420P is formed. By using the grinding process operation, the thickness of the second panel sealing material 420P may be reduced. The second panel sealing material 420P may be ground so that the upper surface of the semiconductor device 600 is exposed. Alternatively, the second panel sealing material 420P may be sufficiently ground so that an end portion of the second vertical wiring unit 700 is exposed. In a subsequent process, the second panel sealing material 420P may become the second sealing material 420 by using a sawing process operation.

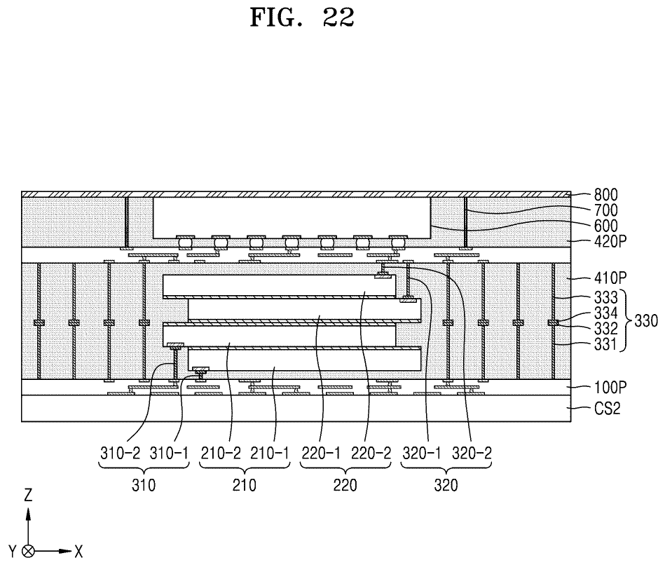

Referring to FIG. 22, the metal layer 800 may be formed on the semiconductor device 600 and the second panel sealing material 420P.

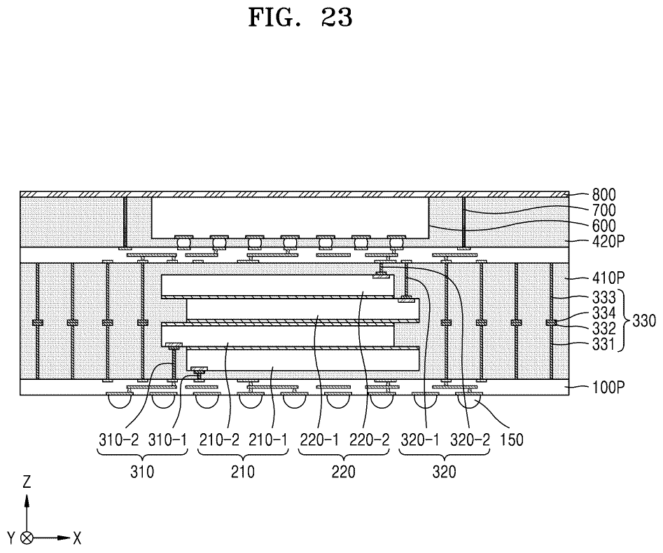

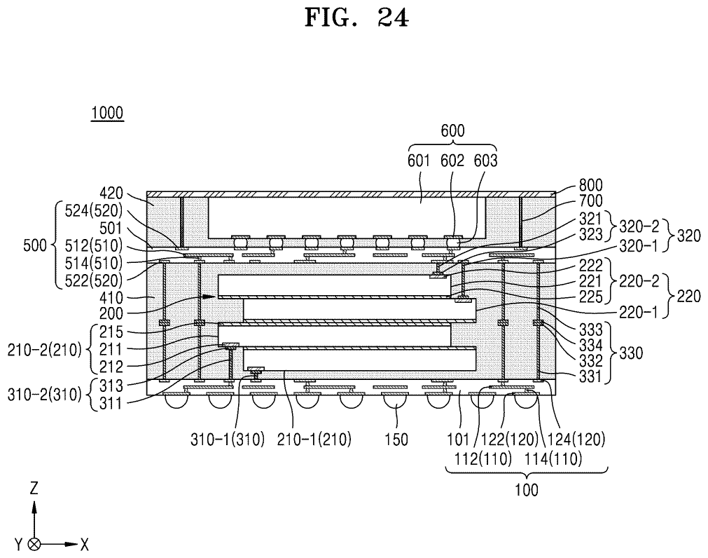

Referring to FIGS. 23 and 24, a carrier substrate CS2 may be removed, and the external connection terminal 150 may be formed under the first panel redistribution substrate 100P. Thereafter, the first panel redistribution substrate 100P, the second panel redistribution substrate 500P, the first panel sealing material 410P, the second panel sealing material 420P, and the metal layer 800 may be cut to correspond to the semiconductor package 1000 by using a sawing process operation. For example, the first panel redistribution substrate 100P, the second panel redistribution substrate 500P, the first panel sealing material 410P, and the second panel sealing material 420P may become the first redistribution substrate 100, the second redistribution substrate 500, the first sealing material 410, and the second sealing material 420 by applying a sawing process operation, respectively. Accordingly, the semiconductor package 1000 including the first redistribution substrate 100, the chip stacked structure 200, the first sub-stack vertical wiring unit 310, the second sub-stack vertical wiring unit 320, the first vertical wiring unit 330, the first sealing material 410, the second sealing material 420, the second redistribution substrate 500, the semiconductor device 600, the second vertical wiring unit 700, and the metal layer 800 may be formed.

While the disclosed concepts has been particularly shown and described with reference to example embodiments thereof, it will be understood by one of ordinary skill in the art that various changes in shape and details may be made therein without departing from the spirit and scope of the disclosed concepts as defined by the following claims. Accordingly, the true scope of protection of the disclosed concepts should be determined by the technical idea of the following claims.

What is claimed is:

1. A semiconductor package comprising:
a first redistribution substrate;
a chip stacked structure including a first sub-stack and a second sub-stack arranged on the first sub-stack, wherein the first sub-stack is arranged apart from the first redistribution substrate above the first redistribution substrate and includes a plurality of semiconductor chips that are stacked, and the second sub-stack includes a plurality of semiconductor chips that are stacked;
a second redistribution substrate arranged on the chip stacked structure;
a first sub-stack vertical wiring unit including vertical wires configured to connect each of the semiconductor chips constituting the first sub-stack to the first redistribution substrate and extend to an upper surface of the first redistribution substrate in a vertical direction; and
a second sub-stack vertical wiring unit including vertical wires configured to connect each of the semiconductor chips constituting the second sub-stack to the second redistribution substrate and extend to a lower surface of the second redistribution substrate in the vertical direction.

2. The semiconductor package of claim 1, further including a first sealing material sealing the chip stacked structure, the first sub-stack vertical wiring unit, and the second sub-stack vertical wiring unit between the first redistribution substrate and the second redistribution substrate;
wherein the semiconductor chips constituting the first sub-stack are arranged so that active surfaces thereof face toward the first redistribution substrate, and
wherein the semiconductor chips constituting the second sub-stack are arranged so that active surfaces thereof face toward the second redistribution substrate.

3. The semiconductor package of claim 1,
wherein the semiconductor chips of the first sub-stack are stacked in a step-type structure so that a portion of a lower surface of each of the semiconductor chips is exposed,
wherein the semiconductor chips of the second sub-stack are stacked in a step-type structure so that a portion of an upper surface of each of the semiconductor chips of the second sub-stack is exposed, and
wherein the semiconductor chip at a lowermost end of the second sub-stack is aligned with the semiconductor chip at a lowermost end of the first sub-stack.

4. The semiconductor package of claim 1,
wherein the first sub-stack is stacked in a step-type structure so that the semiconductor chips thereof are arranged shifted in a first horizontal direction,
wherein the second sub-stack is stacked in the step-type structure so that the semiconductor chips thereof are arranged shifted in an opposite direction to the first horizontal direction, and
wherein the semiconductor chip arranged at a lowermost end of the second sub-stack is aligned with the semiconductor chip arranged at an uppermost end of the first sub-stack.

5. The semiconductor package of claim 1,
wherein a first chip pad is arranged on a lower surface of each of the semiconductor chips of the first sub-stack,
wherein a second chip pad is arranged on an upper surface of each of the semiconductor chips of the second sub-stack,
wherein the first sub-stack vertical wiring unit comprises a first sub-stack contact unit, which is in contact with the first chip pad, and a first sub-stack extension unit extending between the first sub-stack contact unit and the first redistribution substrate, and
wherein the second sub-stack vertical wiring unit comprises a second sub-stack contact unit, which is in contact with the second chip pad, and a second sub-stack extension unit extending between the second sub-stack contact unit and the second redistribution substrate.

6. The semiconductor package of claim 1,
further comprising a first vertical wiring unit configured to be electrically and vertically connected between the first redistribution substrate and the second redistribution substrate,
wherein the first vertical wiring unit comprises a first contact unit arranged on an identical vertical level to an upper surface of the first sub-stack, a first vertical extension unit vertically extending between the first contact unit and the first redistribution substrate, a second contact unit arranged on the first contact unit, and a second vertical extension unit vertically extending between the second contact unit and the second redistribution substrate.

7. The semiconductor package of claim 1, further comprising:
a semiconductor device arranged on the second redistribution substrate;
a metal layer arranged on the semiconductor device; and
a second sealing material sealing between the second redistribution substrate and the metal layer.

8. The semiconductor package of claim 7,
further comprising a second vertical wiring unit arranged apart from the semiconductor device horizontally, configured to be electrically connected between the metal layer and the second redistribution substrate, and providing an electrostatic discharge protection function for the semiconductor device.

9. The semiconductor package of claim 7, wherein at least a portion of the semiconductor device is arranged to vertically overlap the chip stacked structure.

10. The semiconductor package of claim 7,
further comprising a dummy chip arranged horizontally apart from the semiconductor device on the second redistribution substrate,
wherein at least a portion of the dummy chip is arranged to vertically overlap the chip stacked structure.

11. The semiconductor package of claim 1,
wherein a space between the semiconductor chips of the first sub-stack, a space between the semiconductor chips of the second sub-stack, and a space between the semiconductor chip at an uppermost layer of the first sub-stack and the semiconductor chip at a lowermost layer of the second sub-stack are coupled to one another by using adhesive layers.

12. The semiconductor package of claim 1,
wherein a space between the semiconductor chips of the first sub-stack, a space between the semiconductor chips of the second sub-stack, and a space between the semiconductor chip at an uppermost layer of the first sub-stack and the semiconductor chip at a lowermost layer of the second sub-stack are coupled to one another by using a direct bonding operation.

13. The semiconductor package of claim 7,
wherein the semiconductor device comprises a logic chip, and
wherein the chip stacked structure comprises a memory chip.

14. A semiconductor package, comprising:
a first redistribution substrate;
a chip stacked structure including a first sub-stack and a second sub-stack arranged on the first sub-stack, wherein the first sub-stack is arranged on the first redistribution substrate and includes a plurality of semiconductor chips stacked on the first sub-stack and the second sub-stack is arranged on the first sub-stack and includes a plurality of semiconductor chips stacked on the second sub-stack;
a second redistribution substrate arranged on the chip stacked structure;
a first sub-stack vertical wiring unit configured to connect each of the semiconductor chips constituting the first sub-stack except for the semiconductor chip at a lowermost end of the semiconductor chips to the first redistribution substrate and including vertical wires configured to extend to an upper surface of the first redistribution substrate in a vertical direction;
a second sub-stack vertical wiring unit configured to connect each of the semiconductor chips constituting the second sub-stack except for the semiconductor chip at an uppermost end of the semiconductor chips to the second redistribution substrate and including vertical wires configured to extend to a lower surface of the second redistribution substrate in the vertical direction; and
a first sealing material sealing the chip stacked structure, the first sub-stack vertical wiring unit, and the second sub-stack vertical wiring unit between the first redistribution substrate and the second redistribution substrate,
wherein a lower surface of the semiconductor chip at a lowermost end of the semiconductor chips constituting the first sub-stack is coplanar with the upper surface of the first redistribution substrate, and an upper surface of the semiconductor chip at an uppermost end of the semiconductor chips constituting the second sub-stack is coplanar with a lower surface of the second redistribution substrate.

15. The semiconductor package of claim 14,
wherein the semiconductor chips constituting the first sub-stack are arranged so that active surfaces thereof face the first redistribution substrate, and
wherein the semiconductor chips constituting the second sub-stack are arranged so that active surfaces thereof face the second redistribution substrate.

16. The semiconductor package of claim 14,
wherein the semiconductor chips of the first sub-stack are stacked in a step-type structure so that a portion of a lower surface of each of the semiconductor chips of the first sub-stack is exposed,
wherein the semiconductor chips of the second sub-stack are stacked in a step-type structure so that a portion of an upper surface of each of the semiconductor chips of the second sub-stack is exposed, and
wherein the semiconductor chip at a lowermost end of the second sub-stack is aligned with the semiconductor chip at a lowermost end of the first sub-stack.

17. The semiconductor package of claim 14,
further comprising a first vertical wiring unit configured to be electrically and vertically connected between the first redistribution substrate and the second redistribution substrate,
wherein the first vertical wiring unit comprises a first contact unit arranged on an identical vertical level to an upper surface of the first sub-stack, a first vertical extension unit vertically extending between the first contact unit and the first redistribution substrate, a second contact unit arranged on the first contact unit, and a second vertical extension unit vertically extending between the second contact unit and the second redistribution substrate.

18. The semiconductor package of claim 14, further comprising:
a semiconductor device arranged on the second redistribution substrate;
a metal layer arranged on the semiconductor device;
a second vertical wiring unit horizontally arranged apart from the semiconductor device, configured to be electrically connected between the metal layer and the second redistribution substrate, and configured to provide an electrostatic discharge protection function for the semiconductor device; and
a second sealing material sealing the semiconductor device and the second vertical wiring unit between the second redistribution substrate and the metal layer.

19. A semiconductor package comprising:
a first redistribution substrate;
an external connection terminal arranged under a lower surface of the first redistribution substrate;
a chip stacked structure including a first sub-stack and a second sub-stack, which are vertically stacked on the first redistribution substrate;
a second redistribution substrate arranged on the chip stacked structure;
a first sub-stack vertical wiring unit configured to connect the first sub-stack to the first redistribution substrate;
a second sub-stack vertical wiring unit configured to connect the second sub-stack to the second redistribution substrate;
a first vertical wiring unit configured to be electrically and vertically connected between the first redistribution substrate and the second redistribution substrate; and
a first sealing material sealing the chip stacked structure, the first sub-stack vertical wiring unit, and the second sub-stack vertical wiring unit between the first redistribution substrate and the second redistribution substrate,
wherein the first sub-stack comprises a first semiconductor chip arranged apart from the first redistribution substrate on the first redistribution substrate so that an active surface thereof faces toward the first redistribution substrate and a second semiconductor chip stacked shifted on the first semiconductor chip in a first horizontal direction so that an active surface thereof faces toward the first redistribution substrate,
wherein the second sub-stack comprises a third semiconductor chip stacked so that an active surface thereof faces toward the second redistribution substrate and aligned with the first semiconductor chip, and a fourth semiconductor chip stacked so that an active surface thereof faces toward the second redistribution substrate on the third semiconductor chip and aligned to the second semiconductor chip,
wherein the first sub-stack vertical wiring unit comprises a first sub-stack contact unit in contact with a first lower substrate pad arranged on a lower surface of each of the first semiconductor chip and the second semiconductor chip and a first sub-stack extension unit extending between the first sub-stack contact unit and the first redistribution substrate, and
wherein the second sub-stack vertical wiring unit comprises a second sub-stack contact unit in contact with a second upper substrate pad arranged on an upper surface of each of the third semiconductor chip and the fourth semiconductor chip and a second sub-stack extension unit extending between the second sub-stack contact unit and the second redistribution substrate.

20. The semiconductor package of claim 19, further comprising:
a semiconductor device arranged so that at least a portion of the semiconductor device vertically overlaps the chip stacked structure on the second redistribution substrate;
a metal layer arranged on the semiconductor device;
a second vertical wiring unit horizontally arranged apart from the semiconductor device, configured to be electrically connected between the metal layer and the second redistribution substrate, and configured to provide an electrostatic discharge protection function for the semiconductor device; and
a second sealing material sealing the semiconductor device and the second vertical wiring unit between the second redistribution substrate and the metal layer.
